(19) United States
(12) Patent Application Publication
(10) Pub. No.: US 2009/0288700 A1
(43) Pub. Date: Nov. 26, 2009

(54) INTEGRATED DEVICE

(75) Inventors: Herbert Lifka, Eindhoven (NL); Ian French, Brighton (GB)

Correspondence Address: Philips Intellectual Property and Standards, P.O. Box 3001, Briarcliff Manor, NY, 10510-8001, US

(73) Assignee: KONINKLIJKE PHILIPS ELECTRONICS N.V., Eindhoven (NL)

(21) Appl. No.: 12/373,931

(22) PCT Filed: Aug. 6, 2007
(86) PCT No.: PCT/IB07/53087

§ 371 Date: Jan. 15, 2009

(30) Foreign Application Priority Data
Aug. 8, 2006 (EP) 06118574.0

(51) Int. Cl. H01L 31/048; H01L 31/00

(52) U.S. Cl. 136/251; 136/259

(57) ABSTRACT

The present invention relates to an integrated device (10) comprising at least one inorganic photovoltaic cell (16), a substrate supporting the at least one inorganic photovoltaic cell, a prefabricated thin battery (34) coupled to the at least one inorganic photovoltaic cell, and an encapsulation for sealing the integrated device, wherein one of the substrate and the encapsulation is formed by the prefabricated thin battery. The present invention also relates to a method for the manufacturing of such a integrated device.

### TECHNICAL FIELD OF THE INVENTION

The present invention relates to an integrated device comprising at least one inorganic photovoltaic cell and a thin battery coupled to the at least one inorganic photovoltaic cell. The present invention also relates to a method for the manufacturing of such an integrated device.

### BACKGROUND OF THE INVENTION

An example of a device comprising a solar cell and a thin battery is disclosed in the document US2002/0092558. More precisely, the device in US2002/0092558 comprises a transparent ITO-substrate, a thin film solar cell formed on the substrate, a thin film battery formed on the solar cell, which battery receives current produced by the solar cell, and finally a protective layer formed on the battery.

However, full integration of batteries as in US2002/0092558 is quite expensive, since thin film technologies for thick layers require long deposition times using expensive machines. Also, the structure disclosed in US2002/0092558 requires additional packaging to protect the device, which may yield a relatively thick structure. To this end, for many applications, small thickness is an important factor.

### SUMMARY OF THE INVENTION

It is an object of the present invention to overcome these problem, and to provide an improved, integrated device, which device is inexpensive and has a reduced thickness.

These and other objects that will be evident from the following description are achieved by means of an integrated device, and a method for the manufacturing of such an integrated device, according to the appended claims.

According to an aspect of the invention, there is provided an integrated device comprising at least one inorganic photovoltaic cell, a substrate supporting the at least one inorganic photovoltaic cell, a prefabricated thin battery coupled to the at least one inorganic photovoltaic cell, and an encapsulation for sealing the integrated device, wherein one of the substrate and the encapsulation is formed by the prefabricated thin battery.

Thus, the battery gets the function also to act as top encapsulation of the device or act as a supporting and/or protective substrate of the device. This yields a thinner and more robust device compared to prior art structures since a separate encapsulation/substrate can be omitted.

In one embodiment, the substrate is a transparent substrate, the at least one inorganic photovoltaic cell is processed on the transparent substrate, and the prefabricated thin battery is provided on top of the at least one inorganic photovoltaic cell. Thus, here the prefabricated battery acts as the encapsulation of the integrated device. Further, the transparent substrate can be made of a flexible material, allowing the complete device to be flexible.

In another embodiment, the prefabricated thin battery is attached to the at least one inorganic photovoltaic cell, and an encapsulating coating is provided on the other side of the at least one inorganic photovoltaic cell compared to the battery. Thus, here the prefabricated battery acts as the substrate of the integrated device.

In one embodiment, a plurality of inorganic photovoltaic cells are connected in series and coupled to the battery, to achieve a certain voltage.

In one embodiment, the device further comprising an organic light emitting diode (OLED) provided on the opposite side of the battery compared to the at least one inorganic photovoltaic cell, wherein the battery is adapted to power the OLED. The OLED may be a display or a light source, for example. Additionally, the device may further comprise a detector adapted to detect any light originating from the OLED reflected back to the device. The device can for example be used as an on/off switch for an apparatus, which switch is actuated by light originating from the OLED reflected by an external object, such as a user's finger.

In one embodiment, a fixing agent is applied around the at least one inorganic photovoltaic cell and between the at least one inorganic photovoltaic cell and the prefabricated thin battery, which fixing agent comprises a getter material. The getter material is a water absorbing material, such as calcium oxide. Thus, the fixing agent serves to join the at least one inorganic photovoltaic cell and the prefabricated thin battery, as well as to protect the at least one inorganic photovoltaic cell from moisture at the sides of the device.

According to another aspect of the invention, there is provided a method for the manufacturing of an integrated device, comprising providing a transparent substrate, processing at least one inorganic photovoltaic cell on the transparent substrate, and arranging a prefabricated thin battery on top of the at least one inorganic photovoltaic cell for sealing the integrated device. Thus, here the prefabricated battery acts as the encapsulation of the integrated device.

In one embodiment, the method further comprises providing an encapsulating coating on the transparent substrate on the side of the substrate where the at least one inorganic photovoltaic cell is to be processed, and removing the transparent substrate after the at least one inorganic photovoltaic cell has been processed. Thus, here the prefabricated battery acts as the substrate of the integrated device. Preferably, the transparent substrate is removed after the prefabricated battery has been arranged on top of the at least one inorganic photovoltaic cell. The prefabricated thin battery may be arranged on top of the at least one inorganic photovoltaic cell by means of lamination, for example.

In one embodiment, the method further comprises filling the battery with electrolyte after the battery is laminated on top of the at least one inorganic photovoltaic cell. Before the battery is filled with the electrolyte, it is much flatter and will therefore laminate better, which in turn improves the sealing property of the battery.

In one embodiment, the method further comprises arranging an OLED on top of the prefabricated thin battery. The OLED may be a display or a light source and it may be powered by the battery.

### BRIEF DESCRIPTION OF THE DRAWINGS

These and other aspects of the present invention will now be described in more detail, with reference to the appended drawings showing currently preferred embodiments of the invention.

FIG. 1 is schematic cross-sectional side view of an integrated device according to an embodiment of the invention,

FIG. 2 is schematic cross-sectional side view of an integrated device according to another embodiment of the invention,

FIG. 3 is schematic cross-sectional side view of a variant of the integrated device of FIG. 2, and

FIGS. 4a-4b are schematic cross-sectional side views illustrating steps of manufacturing of an integrated device according to yet another embodiment of the invention.

### DETAILED DESCRIPTION OF EMBODIMENTS

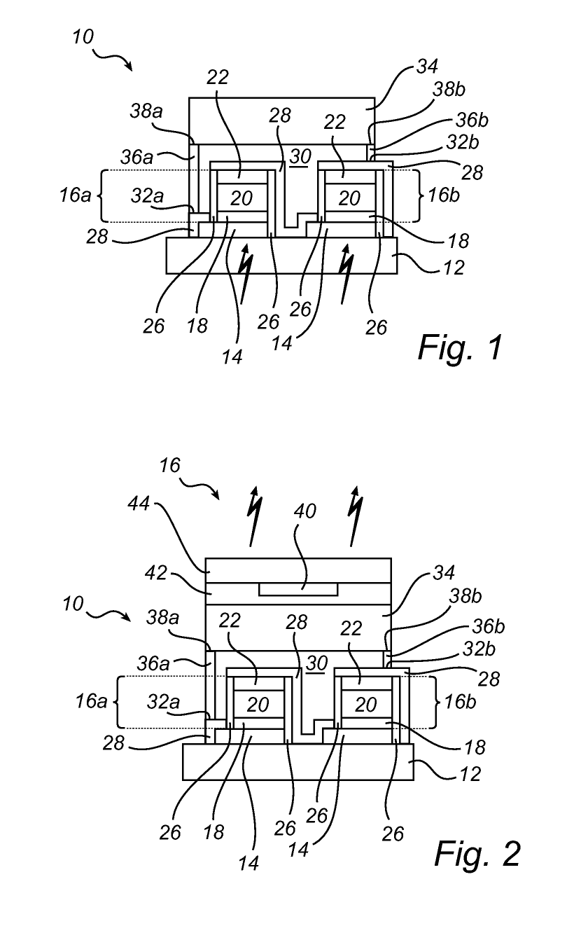

FIG. 1 is a cross-sectional side view of an integrated device 10 according to an embodiment of the invention. The integrated device 10 comprises a substrate 12. The substrate 12 should be a transparent substrate, and it can for example be made of glass or plastics. Onto the substrate 12, ITO layers 14 are deposited with a shadow mask. The ITO layers 14 functions as connection to the forthcoming photovoltaic cells. Onto the ITO layer 14, two inorganic photovoltaic cells (e.g. solar cells) 16a, 16b are processed. Each photovoltaic cell 16 comprises, from bottom to top in FIG. 1, an n-type silicon layer 18, an intrinsic silicon layer 20, and a p-type silicon layer 22, which layers are deposited on top of each other. The area of each ITO layer 14 is somewhat larger than the bas area of the photovoltaic cell 16, to allow electrical connections to the ITO layers 14. SiN 26 is further deposited at the side photovoltaic cells 16 for isolation purposes. Finally, TiN+Al 28 is deposited with a shadow mask such that a contact area 32a is formed on the ITO layer at the bottom of the photovoltaic cell 16a, the top of the photovoltaic cell 16a is connected to the bottom of the photovoltaic cell 16b (via the ITO layer 14 of the photovoltaic cell 16b), and a contact area 32b is formed on the top of the photovoltaic cell 16b.

A glue 30 is then applied over the complete photovoltaic cells 16, for covering and leveling the photovoltaic cells 16, except for contact areas 32a, 32b. The glue 30 is preferably applied by means of printing. Also, a water absorbing getter material such as calcium oxide, CaO, may be incorporated in the glue 30, to protect the cells 16 from moisture from the side of the device. Also, a rim of standard glue (not shown) could be applied around the device (except for the forthcoming battery), to reduce water penetration and thereby further protect the device. Finally, a prefabricated thin battery 34 is placed on top of the glue 30. One pole 38a of the prefabricated battery 34 is connected to the contact area 32a via a first connection 36a, and the other pole 38b of the prefabricated battery 34 is connected to the contact area 32b via a second connection 36b. Thus, the photovoltaic cells 16a, 16b are connected in series to the battery 34, allowing the photovoltaic cells 16 to charge the battery 34. The battery 34 is prefabricated in a sense that incorporating the battery in the device mainly includes assembling the battery with the rest of the device.

No other coating or sealing has to be provided on top of the prefabricated battery 34. Thus, here the prefabricated thin battery 34 acts as a top side encapsulation of the device 10, avoiding the use of any dedicated top encapsulation or sealing. To this end, the prefabricated thin battery 34 should be flat and impermeable with respect to water (water tight) and/or air. An exemplary prefabricated battery having such properties is the Lithylene batteries by Philips. Also, during manufacturing of the integrated device, for some batteries (such as the Lithylene battery, and NiCd- and NiMh batteries) it may be beneficial to fill the battery with electrolyte after mounting of the battery to the device, since the battery is much flatter without the electrolyte. It will then better laminate and therefore seal better.

In the integrated device 10 illustrated in FIG. 1, the thickness of the ITO layer 14 may be in the order of 120 nm, the thickness of the n-type silicon layer 18 in the order of 100 nm, the thickness of the intrinsic silicon layer 20 in the order of 500 nm, the thickness of the p-type silicon layer 22 in the order of 100 nm, the thickness of the TiN in the order of 10 nm, the thickness of the Al in the order of 200 nm, and the thickness of the prefabricated battery 34 in the order of 500 μm.

Even though a single battery 34 is disclosed in FIG. 1, several batteries with associated photovoltaic cells may be provided on a common transparent substrate. The several batteries may be connected in series, in which case the series connected photovoltaic cells of one battery is used in parallel with the series connected photovoltaic cells of another battery.

FIG. 2 is a cross-sectional side view of an integrated device 10 according to another embodiment of the invention. The device of FIG. 2 is similar to that of FIG. 1, except in that an organic light emitting diode (OLED) 40 is provided on top of the prefabricated battery 34. The OLED 40 may be attached to the battery by means of a glue 42, sealed with a glass substrate 44, and connected to the battery 34 for allowing illumination of the OLED 40. The OLED may be a display or a light source. Thus, in this embodiment, an autonomous integrated device is formed, where light is converted to energy by the photovoltaic cells 16, which energy is stored in the battery 34 for use by the OLED 40. The OLED 40 may for example be a battery indicator indicating the status of the battery 34.

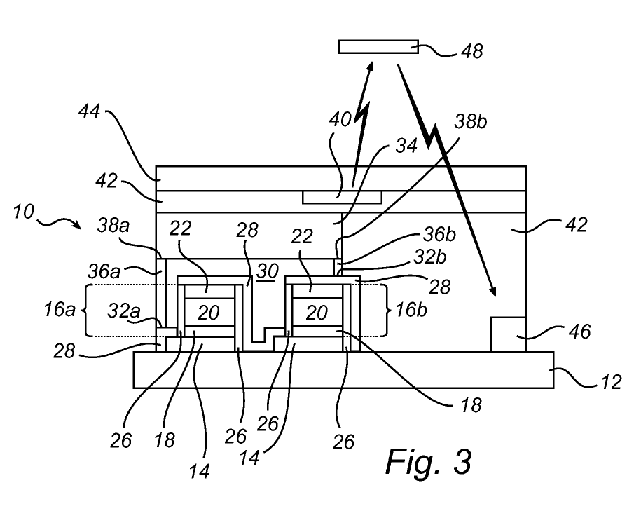

In a variant of the integrated device of FIG. 2, a photo detector 46 is placed on the extended substrate 12 next to the photovoltaic cells 16 and battery 34 and OLED 40, as illustrated in FIG. 3. The photo detector 46 may for example be a PIN diode. Such a PIN diode can be made at the same time as the photovoltaic cells 16 using the same process steps, therefore adding only little extra cost to the device. The photo detector 46 is adapted to detect any light originating from the OLED 40 that is reflected back to the device 10 by an external object 48, such as a user's finger, and take appropriate action upon detection of the reflected light, such a initiating an on or off switch of an apparatus the device is associated with. Other functions may also be initiated, such as dimming, color changing (if more than one color OLED is used), etc.

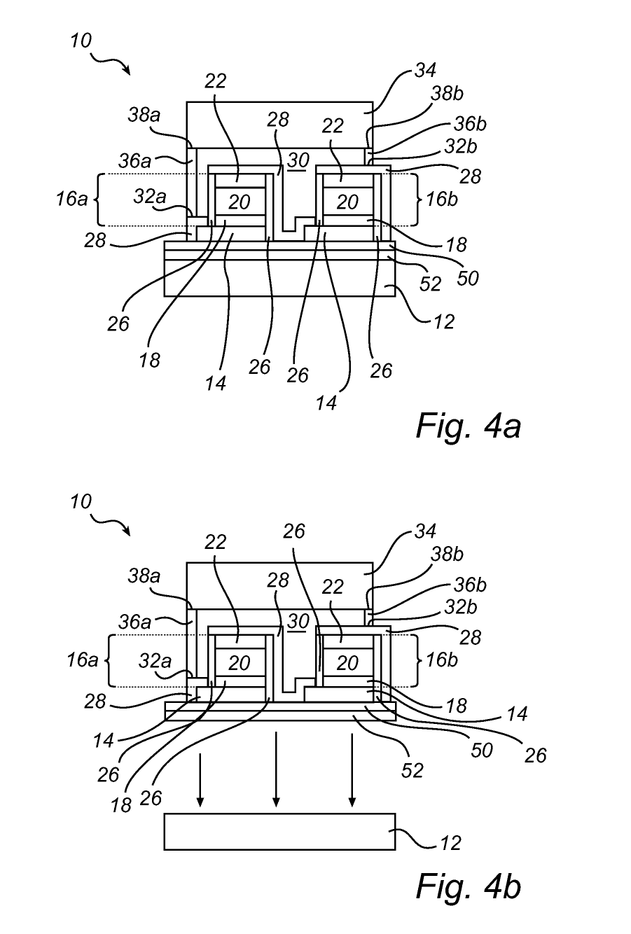

FIGS. 4a-4b are cross-sectional side views illustrating steps of manufacturing of an integrated device 10 according to another embodiment of the invention. The device 10 illustrated in FIG. 4a is similar to that of FIG. 1, except in that an encapsulating coating 50 and a polymer coating 52 is applied between the glass substrate 12 and the rest of the device. In manufacturing, the encapsulating coating 50 and polymer coating 52 are preferably applied to the substrate 12 before the rest of the ITO-layers 14, photovoltaic cells 16, etc. are processed thereon. The encapsulating coating 50 may a NONON-stack (silicon nitride-silicon oxide-silicon nitride-silicon oxide-silicon nitride), and the polymer coating 52 may be made of polyimide.

The substrate 12 may then be released from the polymer coating 52 by means of laser according to the EPLAR process (Electronics on Plastic by Laser Release) as illustrated in FIG. 4b, leaving a final device 10 without the substrate 12, where instead the prefabricated thin battery 34 acts as the device substrate. Without the glass substrate 12, a complete flexible integrated device 10 may be realized. It should be noted that a complete flexible integrated device 10 assumes a flexible battery 34, such as the aforementioned Lithylene battery. However, a rigid device without the substrate 12 is also contemplated.

There are many possible applications for the present invention. The integrated device with the photovoltaic cell and battery can for example be used as a renewable power source in various apparatuses. The integrated device with the photovoltaic cell and battery and OLED can be used as a standalone lamp or display independent of an external power supply. Such a device can advantageously be used as a signaling device in hard to reach places.

The person skilled in the art realizes that the present invention by no means is limited to the preferred embodiments described above. On the contrary, many modifications and variations are possible within the scope of the appended claims. For example, the prefabricated battery may act as a substrate and the glass substrate may be released (as explained in relation to FIGS. 4a-4b) also in the embodiments disclosed in FIGS. 2 and 3.

1. An integrated device, comprising:
at least one inorganic photovoltaic cell,
a substrate supporting the at least one inorganic photovoltaic cell,
a prefabricated thin battery coupled to the at least one inorganic photovoltaic cell,
wherein said prefabricated thin battery is substantially impermeable to water and/or air and sealingly encapsulates the integrated device.

2. An integrated device according to claim 1, wherein the substrate is a transparent substrate, the at least one inorganic photovoltaic cell is processed on the transparent substrate, and the prefabricated thin battery is arranged on top of the at least one inorganic photovoltaic cell for sealing the integrated device.

3. An integrated device according to claim 2, wherein the transparent substrate is made of a flexible material.

4. An integrated device according to claim 1, wherein the prefabricated thin battery is attached to a first side of the at least one inorganic photovoltaic cell for supporting thereof, and an encapsulating coating is provided on an second side of the at least one inorganic photovoltaic cell.

5. An integrated device according to claim 1, comprising a plurality of inorganic photovoltaic cells connected in series and coupled to the prefabricated thin battery.

6. An integrated device according to claim 1, wherein the at least one inorganic photovoltaic cell is attached to a first side of the prefabricated thin battery, the device further comprising an organic light emitting diode (OLED) provided on a second side of the prefabricated thin battery opposite to the first side, wherein the battery is adapted to power the OLED.

7. An integrated device according to claim 6, further comprising a detector for detecting light originating from the OLED reflected back to the device.

8. An integrated device according to claim 1, wherein a fixing agent is applied around the at least one inorganic photovoltaic cell and between the at least one inorganic photovoltaic cell and the prefabricated thin battery, the fixing agent comprising a getter material.

9-14. (canceled)
